(19) United States
(12) Patent Application Publication
(10) Pub. No.: US 2008/0284310 A1
(43) Pub. Date: Nov. 20, 2008

(54) Light emitting device, light source and method of making the device

(75) Inventor: Yoshinobu Suehiro, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/081,703

(22) Filed: Apr. 18, 2008

(30) Foreign Application Priority Data
Apr. 20, 2007 (JP) 2007-112272

(51) Int. Cl. H01L 33/00; H01J 9/02

(52) U.S. Cl. 313/498; 445/51

(57) ABSTRACT

A light emitting device includes a light emitting element, a mounting portion on which the light emitting element is mounted, and a sealing portion formed on the mounting portion for sealing the light emitting element. The sealing portion is formed of a glass material including a light diffusing particle for diffusing light emitted from the light emitting element. The sealing portion is shaped like a rectangular solid. The sealing portion is bonded to the mounting portion by hot pressing, and the light diffusing particle has a melting point higher than temperature during the hot pressing.

The present application is based on Japanese patent application No. 2007-112272 filed on Apr. 20, 2007, the entire contents of which are incorporated herein by reference.

### BACKGROUND OF THE INVENTION

1. Field of the Invention

This invention relates to a light emitting device that a light emitting element is mounted on a base material and sealed with glass. Also, this invention relates to a method of making the light emitting device.

2. Description of the Related Art

Conventionally, a light emitting device is known in which a light emitting element such as an LED (light emitting diode) is sealed with a transparent resin material such as epoxy or silicone-based resin material or a transparent glass material such as phosphate glass. In comparing the resin material with the glass material, since the glass material is generally higher in refractive index than the resin material, the light extraction efficiency from a light emitting element through the glass material is higher than that through the glass material under the conditions that both have the same shape.

WO-2004/082036 A1 discloses a light emitting device using glass as its sealing material. In this light emitting device, a plate glass is bonded by hot pressing onto a substrate on which an LED chip is mounted so as to seal the LED chip. After the hot pressing, the glass with the substrate is separated or cut by using a dicer etc. As shown in FIG. 14, a method for making the light emitting device 401 is conducted such that a glass sealing part 406 for sealing a light emitting element 402 is shaped like a rectangular solid on a substrate 403.

Thus, the light emitting device as disclosed in WO-2004/082036 A1 can exhibit high light extraction efficiency at the light emitting element as well as good mass productivity. On the other hand, light emitted from the light emitting element 402 tends to be confined in the glass sealing part 406 as shown in FIG. 14 since the glass sealing part 406 is high in refractive index and shaped like a rectangular solid. Due to this, the light extraction efficiency of the light emitting device may lower.

### SUMMARY OF THE INVENTION

It is an object of the invention to provide a light emitting device that even when it is shaped like a rectangular solid, reduction in the light extraction efficiency thereof can be suppressed.

It is a further object of the invention to provide a light source using the light emitting device and a method of making the light emitting device.

(1) According to one embodiment of the invention, a light emitting device comprises:

a light emitting element;

a mounting portion on which the light emitting element is mounted; and

a sealing portion formed on the mounting portion for sealing the light emitting element,

wherein the sealing portion comprises a glass material and a light diffusing particle for diffusing light emitted from the light emitting element, and

the sealing portion is shaped like a rectangular solid.

In the above light emitting device, since the light emitting element is sealed by the diffusing particle-dispersed glass, of lights emitted from the light emitting element, light being irradiated to the diffusing particle can be diffused in the glass sealing portion and then reaches the light extraction surface of the glass sealing portion. Thereby, even when the glass sealing portion is shaped like the rectangular solid, light to be confined within the glass sealing portion in case of having no diffusing particle can be extracted from the glass sealing portion. Further, in the embodiment, since the diffusing particles are dispersed in the glass sealing portion, light can be prevented from being confined inside a diffusion layer as occurred in prior art where the diffusion layer is formed by a diffusing material.

In the above embodiment (1), the following modifications, changes and a combination thereof can be made.

(i) The sealing portion is bonded to the mounting portion by hot pressing, and the light diffusing particle comprises a melting point higher than temperature during the hot pressing.

(ii) The light diffusing particle comprises a particle diameter corresponding to one to nine times a wavelength of light emitted from the light emitting element.

(iii) The light diffusing particle comprises a white particle.

(iv) The light diffusing particle comprises a zirconia particle.

(v) The light diffusing particle comprises an alumina particle.

(vi) The light emitting element comprises a plurality of light emitting element on the one mounting portion.

(vii) The glass material comprises a void formed therein.

(viii) The sealing portion further comprises a phosphor for radiating a wavelength-converted light when being excited by light emitted from the light emitting element.

(ix) The glass material comprises a ZnO—SiO₂—R₂O-based glass material, where R is an element selected from group I elements.

(2) According to another embodiment of the invention, a light source comprises:

the light emitting device of the above embodiment (1); and

a focusing optical system for collecting light emitted from the light emitting device in a predetermined direction.

In the above embodiment (2), the following modifications, changes and a combination thereof can be made.

(x) The light emitting device further comprises a heat radiation pattern formed on the mounting portion, and

the light source further comprises a heat radiator connected to the heat radiation pattern.

(3) According to another embodiment of the invention, a method for making the light emitting device of the above embodiment (1) comprises:

mixing a powder glass with a powder light diffusing particle to form a mixed powder with the light diffusing particle dispersed in the glass;

melting the mixed powder and then solidifying the melted to have a plate diffusing particle-dispersed glass;

fusion-bonding the diffusing particle-dispersed glass to the mounting portion with the plural light emitting elements mounted thereon by hot pressing to have an intermediate product comprising the plural light emitting elements sealed by the diffusing particle-dispersed glass formed on the mounting portion; and

dividing the intermediate product by a dividing means to have the light emitting device.

### BRIEF DESCRIPTION OF THE DRAWINGS

The preferred embodiments according to the invention will be explained below referring to the drawings, wherein:

FIG. 1 is a cross sectional view showing a light emitting device in a first preferred embodiment according to the invention;

FIG. 2 is a cross sectional view showing a light emitting element in FIG. 1;

FIG. 3 is a flow chart showing a method of making the light emitting device;

FIGS. 4A to 4C are cross sectional views showing a method of processing a diffusing particle-dispersed glass, where FIG. 4A shows an apparatus for producing the diffusing particle-dispersed glass from a mixed power, FIG. 4B shows the diffusing particle-dispersed glass produced from a mixed power, and FIG. 4C shows the sliced diffusing particle-dispersed glasses;

FIG. 5 is a cross sectional view showing a state of being processed by hot pressing;

FIG. 6 is a schematic cross sectional view showing an example of optical path emitted from the LED element;

FIG. 7 is a cross sectional view showing a modification of the first embodiment;

FIG. 8 is a cross sectional view showing a light emitting device in a second preferred embodiment according to the invention;

FIG. 9 is a top view showing a circuit pattern formed on an element mounting substrate;

FIG. 10 is a top view showing a modification of the second embodiment, where a circuit pattern is formed on the element mounting substrate;

FIG. 11 is a top view showing a light source in a third preferred embodiment according to the invention;

FIG. 12 is a cross sectional view cut along a line A-A in FIG. 11;

FIG. 13 is a cross sectional view cut along a line B-B in FIG. 11; and

FIG. 14 is a schematic cross sectional view showing an example of optical path emitted from the LED element in the conventional light emitting device.

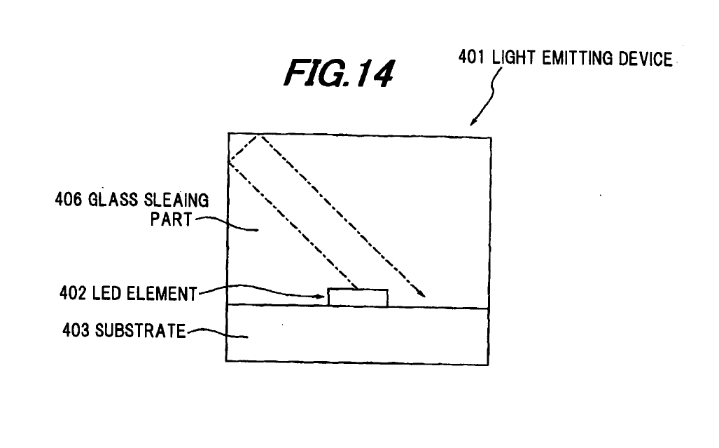

### DETAILED DESCRIPTION OF THE PREFERRED EMBODIMENTS

### First Embodiment

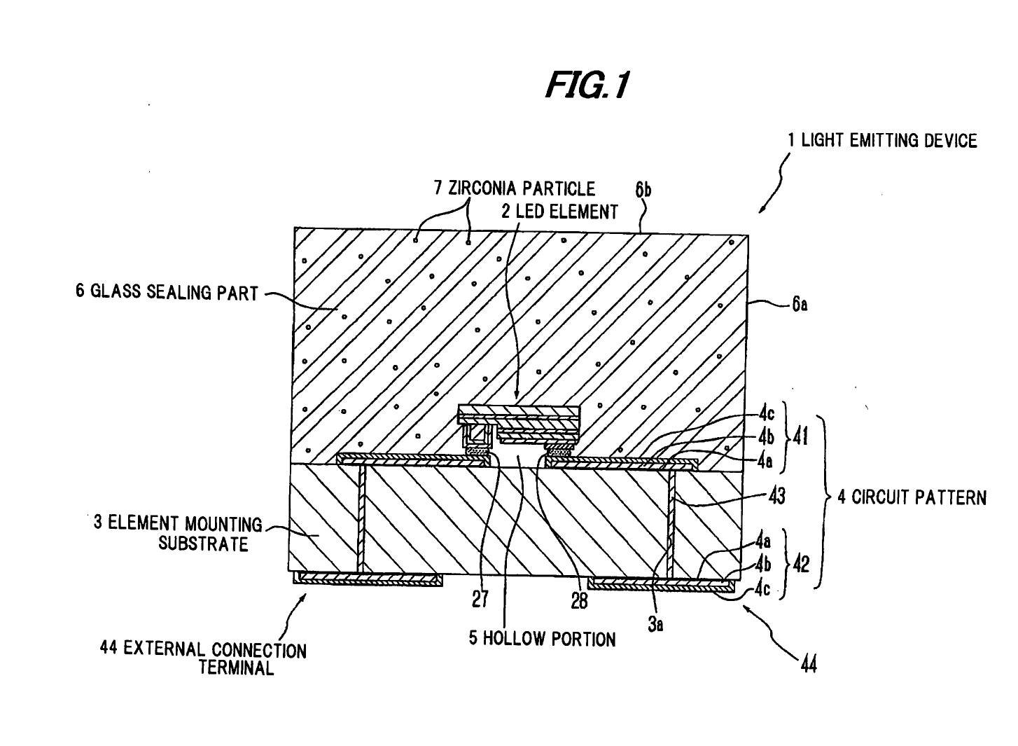

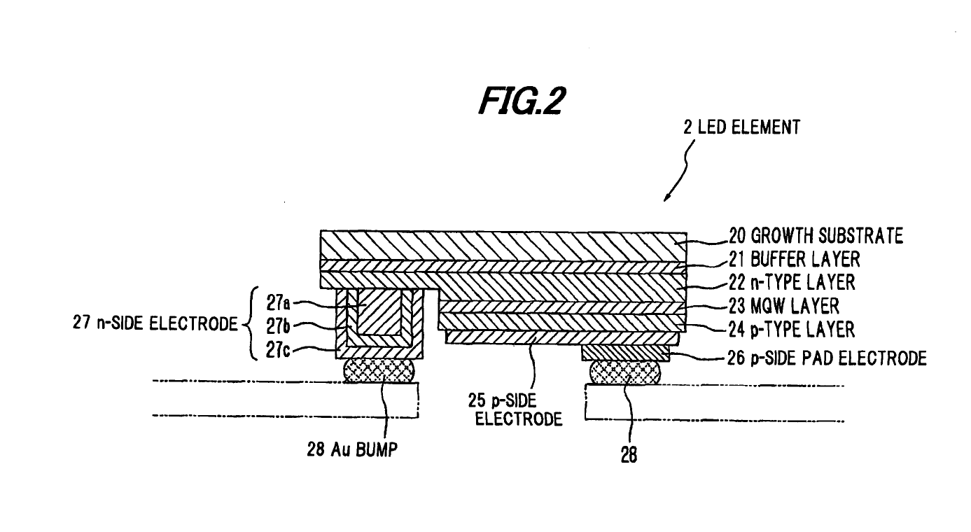

FIGS. 1 to 6 show the first preferred embodiment of the invention. FIG. 1 is a cross sectional view showing a light emitting device in the first preferred embodiment according to the invention, and FIG. 2 is a cross sectional view showing a light emitting element in FIG. 1.

As shown FIG. 1, the light emitting device 1 comprises a flip-chip type LED element 2 formed of GaN-based semiconductor material, an element mounting substrate 3 on which the LED element 2 is mounted, a circuit pattern 4 formed on the element mounting substrate 3 and of tungsten (W)-nickel (Ni)-gold (Au), and a glass sealing part 6 which seals the LED element 2 while being bonded to the element mounting substrate 3 and contains zirconia particles 7. Between the LED element 2 and the element mounting substrate 3, an empty space (or void) is formed into which the glass is not penetrated (i.e., no glass existing therein). In this embodiment, the element mounting substrate 3 and the circuit pattern 4 compose a mounting portion for mounting the LED element 2 thereon and supplying power to the LED element 2.

As shown FIG. 2, the LED element 2 as a light emitting element is composed of, epitaxially grown on the surface of a growth substrate 20 of sapphire (Al₂O₃), a buffer layer 21, an n-type layer 22, an MQW layer 22 and a p-type layer 24 which are of group III nitride semiconductor and formed in this order. The LED element 2 is epitaxially grown at 700° C. or more, upper temperature limit thereof is 600° C. or more, and it is stable at temperature during sealing process using low-melting heat melting glass. Further, the LED element 2 is provided with a p-side electrode 25 formed on the surface of the p-type layer 24, a p-side pad electrode 26 formed on the p-side electrode 25, and an n-side electrode 27 formed on the n-type layer 22 exposed partially by etching the p-type layer 24 through the n-type layer 22. Au bumps 28 are formed on the p-side pad electrode 26 and the n-side electrode 27, respectively.

The p-side electrode 25 is of, e.g., rhodium (Rh) and serves as a light reflection layer for reflecting light emitted from the MQW layer 23 as a light-emitting layer in the direction of the growth substrate 20. The material of the p-side electrode 25 can be suitably changed. In this embodiment, the two p-side pad electrodes 26 are formed on the p-side electrode 25, and the Au bump 28 is formed on each of the p-side pad electrodes 26. Alternatively, the number of the p-side pad electrodes 26 formed on the p-side electrode 25 may be suitably increased to, e.g., three or more.

The n-side electrode 27 is composed of a contact layer and a pad layer formed on the same area. As shown in FIG. 2, the n-side electrode 27 is composed of an Al layer 27a, a thin-film Ni layer 27b covering the Al layer 27a, and an Au layer 27c covering the Ni layer 27b. The material of the n-side electrode 27 can be suitably changed. In this embodiment, the n-side electrode 27 is formed at the corner of the LED element 2 in top view, and the p-side electrode 25 is formed on the entire surface of the LED element 2 except the area where the n-electrode 25 is formed.

The LED element 2 is 100 μm in thickness, 346 μm square in chip size, and 7×10⁻⁶/° C. in thermal expansion coefficient (α). Although the GaN layer of the LED element 2 is 5×10⁻⁶/° C. in thermal expansion coefficient (α), the overall LED element 2 has the same thermal expansion coefficient (α) as the growth substrate 20 since the sapphire growth substrate 20 occupying the large part thereof is 7×10⁻⁶/° C. in thermal expansion coefficient (α). In FIGS. 1 to 2, the respective components are shown in dimensions different from the actual dimensions for emphasizing them.

The element mounting substrate 3 is of alumina (Al₂O₃) polycrystal sintered material, 0.25 mm in thickness, 1.0 mm square in chip size, and 7×10⁻⁶/° C. in thermal expansion coefficient (α). As shown in FIG. 1, the circuit pattern 4 of the element mounting substrate 3 is composed of a surface pattern 41 formed on the surface of the substrate and electrically connected to the LED element 2, and a back surface pattern 42 formed on the back surface of the substrate and adapted to be connected to an external terminal. The surface pattern 41 comprises a W layer 4a patterned according to the shape of the electrode of the LED elements 2, a thin-film Ni layer 4b covering the surface of the W layer 4a, and a thin-film Au layer 4c covering the surface of the Ni layer 4b. The back surface pattern 42 comprises a W layer 4a patterned according to the shape of an external connection terminal 44 as described later, a thin-film Ni layer 4b covering the surface of the W layer 4a, and a thin-film Au layer 4c covering the surface of the Ni layer 4b. The surface pattern 41 and the back surface pattern 42 are electrically connected each other through a via pattern 43 which is formed of W and formed in a via hole 3a penetrating the mounting substrate 3 in thickness direction. The external connection terminal 44 is one by one formed at the anode and cathode sides. The external connection terminals 44 are diagonally disposed on the element mounting substrate 3 in top view.

The glass sealing part 6 is formed of ZnO—B₂O₃—SiO₂—Nb₂O₃—Na₂O—Li₂O-based heat melting glass with the zirconia particles 7 as a light diffusing particle uniformly dispersed therein. The composition of the glass is not always limited to this, and the heat melting glass may not include Li₂O and optionally include ZrO₂, TiO₂ etc. As shown in FIG. 1, the glass sealing part 6 is shaped like a rectangular solid on the element mounting substrate 3. The side face 6a of the glass sealing part 6 is formed by cutting by using a dicer a plate glass with the element mounting substrate 3 bonded thereto by hot pressing. The top surface 6b of the glass sealing part 6 is a surface of the plate glass bonded to the element mounting substrate 3 by hot pressing. The heat melting glass for the glass sealing part 6 is 490° C. in glass transition temperature (Tg) and 520° C. in yielding point, where the glass transition temperature (Tg) is sufficiently lower than formation temperature for forming the epitaxial growth layer of the LED element 2. In this embodiment, the glass transition temperature (Tg) is by 200° C. or more lower than the formation temperature of the epitaxial growth layer. The thermal expansion coefficient (α) of the heat melting glass is 6×10⁻⁶/° C. at temperature of 100° C. to 300° C. The thermal expansion coefficient (α) becomes larger than this value beyond the glass transition temperature (Tg). This allows the heat melting glass to be processed by hot pressing to be bonded to the element mounting substrate 3 at 600° C. The heat melting glass for the glass sealing part 6 is 1.7 in refractive index.

The composition of the heat melting glass can be arbitrarily determined if the glass transition temperature (Tg) thereof is lower than the allowable temperature limit of the LED element 2 and the thermal expansion coefficient (α) thereof is approximately the same as the element mounting substrate 3. Glasses with a relatively small glass transition temperature (Tg) and a relatively small thermal expansion coefficient (α) can include, e.g., ZnO—SiO₂—R₂O based glass (where R is at least one selected from group I elements such as Li, Na and K), phosphate-based glass, lead glass etc. Of these glasses, the ZnO—SiO₂—R₂O based glass is preferable since it is better in humidity resistance than the phosphate-based glass and does not cause environmental problem as in the lead glass.

The heat melting glass is glass formed while being melted or softened by heating and is different from glass, i.e., sol-gel glass, formed by the sol-gel process. The sol-gel glass can cause a crack due to its big volume change in formation and therefore it is difficult to form the sol-gel glass into a thick film. However, the heat melting glass can avoid this problem. Further, the sol-gel glass is likely to be porous so that it may be poor in airtightness. However, the heat melting glass does not cause this problem so that the LED element 2 can be surely sealed.

The heat melting glass is generally processed at a different order of viscosity much higher than resin with a high viscosity level. In case of the glass, even if beyond the yielding point by several tens of ° C., the viscosity cannot be reduced down to the general resin sealing level. If the viscosity is brought to the general resin sealing level by heating at high temperature beyond the crystal growth temperature of the LED element, it will stick to the mold and therefore it is difficult to handle it in sealing and molding process. Therefore, it is preferable to process the heat melting glass at 10⁴ poise or higher.

The zirconia particle 7 is a white particle to diffuse light emitted from the MQW layer of the LED elements 2. The zirconia particles 7 is 2700° C. in melting point which is much higher than the glass processing temperature. For example, the zirconia particles 7 are 2 μm in average diameter and 2 ppm in its concentration in the glass sealing part 6. When the average diameter of the zirconia particles 7 is made 0.2 to 10 μm, the diffusion effect per unit weight thereof can be preferably increased so as to improve the light extraction efficiency by the diffusion while preventing undesired influence in physical property such as being fragile in glass strength. Further, when the average diameter of the zirconia particles 7 is made 0.5 to 4 μm which corresponds to one to several times wavelength of blue light, Mie scattering (i.e., scattering by particles with a diameter at wavelength level) can be preferably yielded. Considering the conditions for yielding the Mie scattering independently from the average diameter and particle size distribution, the zirconia particle 7 needs to contain particles with a diameter one to nine times the wavelength of blue light. If the zirconia particles 7 are made 0.5 to 4 μm in average diameter and 20 ppm or less in concentration, the undesired influence in physical property can be suppressed and reduction in light extraction efficiency caused by excessive diffusion effect can be prevented. With the particle size in the above order, sufficient diffusion (scattering) effect can be obtained even when the particles contained in the glass are so few that its concentration is difficult to measure.

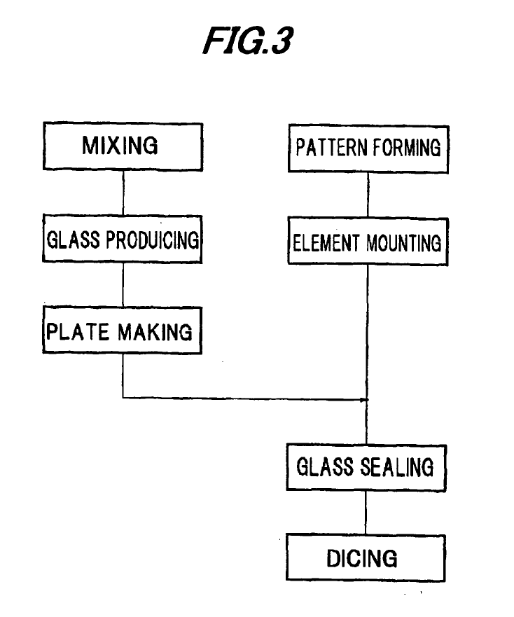

A method of making the light emitting device 1 will be described below referring to the flow chart in FIG. 3.

First, ZnO—B₂O₃—SiO₂—Nb₂O₃—Na₂O—Li₂O-based heat melting glass is crushed to pieces for producing glass powder with average diameter of 30 μm. The zirconia particles 7 with average diameter of 2 μm are mixed herewith so as to yield mixed powder 10 in which the zirconia particles 7 are dispersed uniformly (Mixing Step). In case of using a ball mill for crushing the heat melting glass, zirconia may be used for either a pot or a ball such that the zirconia particles 7 are automatically mixed during the crushing of glass, where a separate step for mixing the zirconia particles 7 becomes unnecessary. If the zirconia particles 7 are excessive in the mixed powder 10, the amount of the zirconia particles 7 can be controlled by removing the excess by classification.

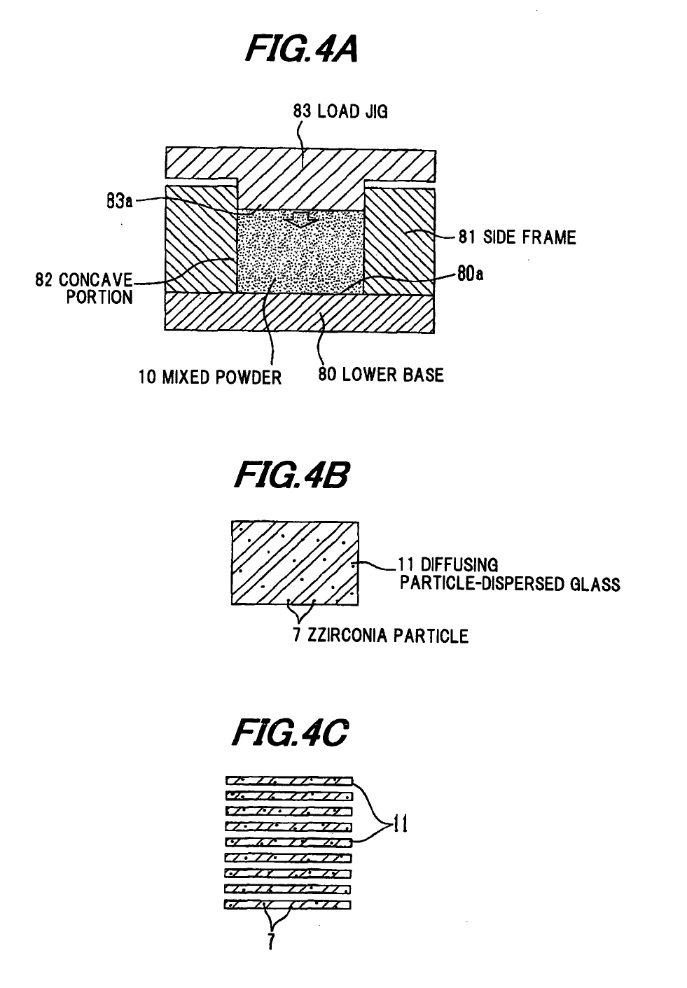

FIGS. 4A to 4C are cross sectional views showing a method of processing a diffusing particle-dispersed glass, where FIG. 4A shows an apparatus for producing the diffusing particle-dispersed glass from a mixed power, FIG. 4B shows the diffusing particle-dispersed glass produced from a mixed power, and FIG. 4C shows the sliced diffusing particle-dispersed glasses.

After the mixed powder 10 thus obtained in the mixing step is melted applying a load thereto, it is solidified to produce the diffusing particle-dispersed glass 11 (Glass Producing Step). For example, as shown in FIG. 4A, a tubular side frame 81 for surrounding a predetermined area on a lower base 80 is disposed on the flat surface 80a of the lower base 80 so as to form a concave portion 82 with its top opened. The concave portion 82 has the same cross section overall in the vertical direction such that the lower part 83a of a load jig 83 shaped according to the section of the concave portion 82 can be moved vertically in the concave portion 82. After the mixed powder 10 is filled in the concave portion 82, the load jig 83 for pressing the inside of the concave portion 82 is placed thereon. Applying a pressure of 20 kg/cm² to the mixed powder 10 by using the load jig 83, the mixed powder 10 is melted at 650° C. in 7.6 Torr vacuum atmosphere. In such a case, the zirconia particles 7 are difficult to melt into the glass since its melting point is 2700° C.

Then, by cooling the melted mixed powder 10 to solidify it, as shown in FIG. 4B, the diffusing particle-dispersed glass 11 with the zirconia particles 7 dispersed therein can be obtained. Then, as shown in FIG. 4C, the diffusing particle-dispersed glass 11 thus obtained is sliced into plate-like materials according to the thickness of the glass sealing part 6 (Plate Making Step). In this embodiment, the glass sealing part 6 is 0.5 mm in thickness.

Separately from the diffusing particle-dispersed glass 11, the element mounting substrate 3 with the via hole 3a formed therein is prepared. First, W paste is screen-printed on the surface of the element mounting substrate 3 according to the circuit pattern 4. Then, the element mounting substrate 3 with the W paste printed thereon is heated at about 1000° C. so as to baking the W onto the element mounting substrate 3. Then, on the W, Ni plating and Au plating are made to form the circuit pattern 4 (Pattern Forming Step).

Then, plural LED elements 2 are electrically bonded through the Au bump 28 to the surface pattern 41 of the circuit pattern 4 on the element mounting substrate 3 (Element Mounting Step). In this embodiment, for each LED element 2, three bumps are in total formed, two for the p-side electrode and one for the n-side electrode.

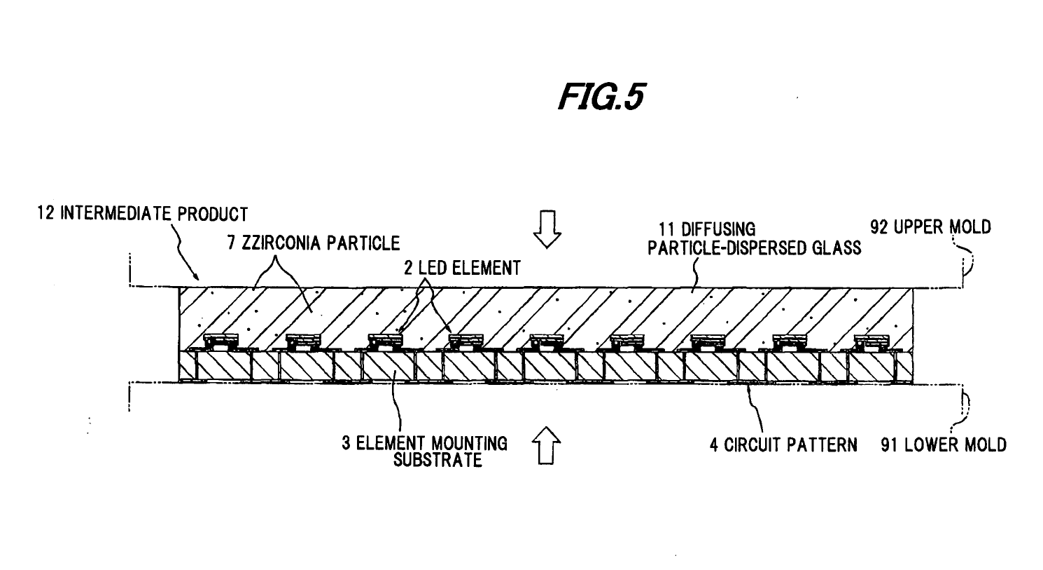

Then, the element mounting substrate 3 with the LED elements 2 mounted thereon is placed on a lower mold 91 and the plate diffusing particle-dispersed glass 11 is placed on an upper mold 92. The lower mold 91 and the upper mold 92 are each equipped with a heater, and can be temperature-controlled independently from each other. Then, as shown in FIG. 5, the diffusing particle-dispersed glass 11 is stacked on the nearly flat mounting surface of the element mounting substrate 3, and hot pressing thereof is conducted in nitrogen atmosphere by pressing the lower mold 91 and the upper mold 92 against each other. Thereby, the diffusing particle-dispersed glass 11 is fusion-bonded to the element mounting substrate 3 with the LED elements 2 mounted thereon, so that the LED element 2 can be sealed with the diffusing particle-dispersed glass 11 on the element mounting substrate 3 (Glass Sealing Step). FIG. 5 is a cross sectional view showing a state of being processed by hot pressing. In this embodiment, the working pressure of the hot pressing is about 20 to 40 kgf/cm². In such a case, the hot pressing only has to be conducted in atmosphere inert to the respective components. For example, it may be conducted in vacuum rather than the nitrogen atmosphere.

By the hot pressing, the diffusing particle-dispersed glass 11 can be bonded to the element mounting substrate 3 through oxides included therein. It is preferable that the viscosity of the heat melting glass during the hot pressing is 10⁵ to 10⁷ poises. In this viscosity range, the product yield can be enhanced since the glass can be prevented from sticking to the upper mold 92 and from effusing due to low viscosity, or from decreasing in bonding strength to the element mounting substrate 3 and from increasing the crushed Au bump 28 due to high viscosity.

The element mounting substrate 3 is of polycrystal alumina and roughened in its surface. The interface of the bonding portion on the glass sealing part 6 side is roughened along the surface of the element mounting substrate 3. The surface roughening can be made by, e.g., conducting the hot pressing in atmosphere with a reduced pressure lower than atmospheric pressure. If the situation allows the glass to be penetrated into the recess of the roughened polycrystal alumina, the pressure conditions and the atmosphere vacuum conditions during the hot pressing may be arbitrarily chosen. For example, either the pressure conditions or the atmosphere vacuum conditions during the hot pressing may be solely conducted. As a result, any gaps can be removed between the glass sealing part 6 and the element mounting substrate 3 so as to secure the bonding strength between the glass sealing part 6 and the element mounting substrate 3.

In order to shorten the cycle time required for the hot pressing, a preheat stage before the pressing may be arranged to preheat the glass sealing part 6 or a cooling stage after the pressing may be arranged to control the cooling speed of the glass sealing part 6. Alternatively, the pressing may be also conducted on the preheat stage and the cooling stage. Thus, the stages during the hot pressing can be suitably changed.

Thus, as shown in FIG. 5, an intermediate product 12 is prepared where the plural light emitting devices 1 are not separated yet as well as being bonded together in the lateral direction. Then, the element mounting substrate 3 with the glass sealing part 6 united therewith is set in a dicer, which allows it to be divided into the separate light emitting device 1 according to each LED element 2 (Dicing Step). The glass sealing part 6 and the element mounting substrate 3 are cut concurrently by the dicer, so that they can have a plane in common.

In operation for the light emitting device 1 thus composed, when voltage is applied through the circuit pattern 4 to the LED element 2, blue light is emitted from the LED element 2.

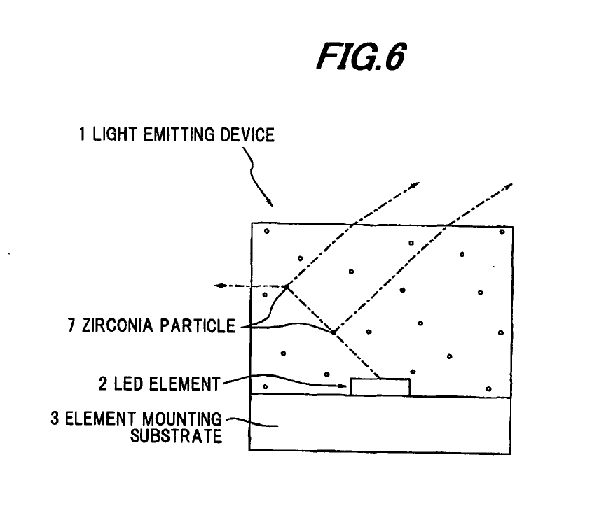

FIG. 6 is a schematic cross sectional view showing an example of optical path emitted from the LED element. The LED element 2 of the light emitting device 1 is sealed by the glass with the zirconia particles 7 dispersed therein. Therefore, of lights emitted from the LED element 2, as shown in FIG. 6, light irradiated to the zirconia particles 7 is diffused thereby in the glass sealing part 6 and then reaches the surface of the glass sealing part 6. Therefore, light to be confined within the glass sealing part 6 in case of having no zirconia particles 7 can be extracted from the glass sealing part 6. For example, although the light extraction efficiency was about 70% when the glass sealing part 6 is formed cubic and does not have the zirconia particles 7, it can be increased to about 90% by the zirconia particles 7. Thus, by using the glass material, deterioration of the sealing part in the LED element 2 can be prevented, and reduction in light extraction efficiency can be prevented even when the glass sealing part 6 is formed into rectangular solid.

The melting point of the zirconia particles 7 is higher than temperature during the hot pressing, so that the zirconia particles 7 are not melted with the glass during the processing of the glass sealing part 6 and can be kept stably in particle form in the glass sealing part 6. Further, since the zirconia particles 7 are white, they do not absorb light from the LED element 2.

In this embodiment, since the mixed powder 10 is melted while applying a load thereto, it can be melted at temperature lower than that in case of applying no load. Further, since the process can be conducted near yielding point (At), the glass can be stably prevented from being not crystallized even when using unstable ZnO-based glass. Alternatively, by melting the glass without applying a load, the zirconia particles 7 may be uniformly dispersed therein. Also, the glass may be melted by applying a pressure of 50 kgf/cm² by using a pressing machine. The extent of the reduced-pressure atmosphere and the applied pressure can be suitably adjusted according to the properties of glass. It is not always necessary to use both the reduced-pressure atmosphere and the applied pressure. In other words, the glass may be melted by using either one of the reduced-pressure atmosphere and the applied pressure.

The glass sealing part 6 is formed of ZnO—B₂O₃—SiO₂—Nb₂O₃—Na₂O—Li₂O-based heat melting glass, so that it can be excellent in stability and weather resistance. Therefore, even when the light emitting device 1 is used under severe environments for a long period, the glass sealing part 6 can be prevented from deteriorating so as to suppress a temporal reduction in light extraction efficiency. Further, since the glass sealing part 6 has a high refractive index and high transmissivity, the device can have both high reliability and high emission efficiency.

The glass sealing part 6 is formed of glass having a yielding point (At) lower than the epitaxial growth temperature of semiconductor layers of the LED element 2. Therefore, the LED element 2 is not subjected to thermal damage during the hot pressing and can be processed at temperature sufficiently low as compared to the crystal growth temperature of the semiconductor layers.

Since the element mounting substrate 3 and the glass sealing part 6 are bonded each other through oxide chemical bonding, the sealing strength can be further enhanced. This allows the practical application of a small package with a small bonding area.

The element mounting substrate 3 and the glass sealing part 6 are nearly equal in thermal expansion coefficient (α) so that bonding failure such as peeling and cracking is difficult to occur even when being left at room temperature or low temperature after being bonded at high temperature. In general, glasses have the property that thermal expansion coefficient (α) thereof increases at temperature beyond its glass transition temperature (Tg). Thus, when the glass sealing is conducted at temperature higher than Tg, it is preferable to take into account a thermal expansion coefficient (α) at temperature higher than Tg as well as that at temperature lower than Tg so as to conduct the stable glass sealing. In other words, by allowing a glass material composing the glass scaling part 6 to have thermal expansion coefficient (α) nearly equal to thermal expansion coefficient (α) at temperature higher than Tg as well as that of the element mounting substrate 3, internal stress causing warpage of the element mounting substrate 3 can be reduced. Therefore, shear failure in glass can be prevented that may arise although the bonding strength can be secured between the element mounting substrate 3 and the glass sealing part 6. Thus, the element mounting substrate 3 and the glass sealing part 6 can be enlarged in size so as to increase the number of elements producible together. It is confirmed by the inventors that the peeling or cracking does not occur after 1000 cycles of wet thermal shock test in the range of −40° C. to 100° C. Further, it is confirmed that, where, for combinations of glass and ceramic substrate with different thermal expansion coefficients, the test is conducted that a 5 mm×5 mm glass piece is bonded to a ceramic substrate, if the ratio of one material (of the glass and the ceramic substrate) with a lower thermal expansion coefficient to the other material with a lower thermal expansion coefficient is 0.85 or more, they can be bonded to each other without cracks. Being nearly equal in thermal expansion coefficient can be defined as this ratio range (0.85 or more), although it depends on the rigidity or size of material.

Since the LED element 2 is flip-mounted without using any wires, no problem occurs at electrodes thereof even when pressing the glass at high viscosity. The viscosity of the heat melting glass during the sealing step is as high as 10⁴ to 10⁸ poises, which is in physical property very different from epoxy resins that is in liquid phase at a viscosity of about 5 poises before being thermally hardened. Therefore, when sealing with the glass a face-up type LED element that uses wires for electrically connecting electrodes formed on its surface to a power feeding member such as a lead, the wires may be crushed or deformed. However, the LED element 2 of this embodiment can avoid this problem. On the other hand, when sealing a flip-chip type LED element which is flip-mounted on a power feeding member such as a lead through Au bumps or so, crush of the bumps or shortening between the bumps may be caused by pressure applied to the LED element due to the high viscosity of glass. However, the LED element 2 of this embodiment can avoid this problem.

The surface pattern 41 of the element mounting substrate 3 is drawn to the back surface pattern 42 through the via pattern 43. Therefore, the production process can be simplified without requiring special countermeasures against the problems that the glass material penetrates into unnecessary sites and that the electrical terminal is covered with the glass material. Further, since the plural LED elements 2 are simultaneously sealed by the plate diffusing particle-dispersed glass 11, the plural light emitting devices 1 can be easily mass-produced by dicing. Meanwhile, since the heat melting glass is processed at high viscosity, the mass-production can be sufficiently achieved if only the external terminals are drawn to the back surface even without using the via holes, where the countermeasures required for the resin sealing are not necessary.

The LED elements 2 are flip-chip mounted, so that the ultra-small light emitting device 1 such as 0.5 mm square can be realized as well as solving the problems in conducting the glass sealing process. This is because the boding space for wires is not needed and no peeling at the interface occurs even at a small bonding space since the glass sealing part 6 and the element mounting substrate 3 have substantially the same thermal expansion coefficients and are securely bonded based on the chemical bonding.

The LED element 2 and the glass sealing part 6 have substantially the same thermal expansion coefficients. Thus, since all the adjacent members including the element mounting substrate 3 have substantially the same thermal expansion coefficients, the internal stress caused can be very low even in the temperature difference between high temperature during the glass sealing process and room temperature, so that stable workability can be obtained without generating cracks. Further, the internal stress can be thus reduced to enhance the impact resistance, so that the glass sealing type LED with high reliability can be obtained.

The element mounting substrate 3 is formed of alumina (Al₂O₃), so that the parts cost can be reduced, and the reduction in device cost can be realized as well as the mass productivity since it is readily available. Further, Al₂O₃ has a good thermal conductivity, so that it can be sufficiently adapted to high brightness or high output type devices. Furthermore, since the element mounting substrate 3 has a small light absorption, it is optically advantageous.

Although in the first embodiment, the light emitting device 1 uses the LED element 2 made of a GaN based semiconductor material, the LED element is not limited to the GaN based LED element 2, and may be made of another semiconductor material such as ZnSe based and SiC based semiconductor materials.

The LED element 2 may be produced by scribing. In this case, the LED element 2 produced by scribing may have on a side surface thereof, as a cut section, a sharpened concavity and convexity, and the side surface of the LED element 2 is preferably coated by an element coating material. The element coating material includes SiO₂ based coating material with optical transparency. The element coating material can prevent the occurrence of cracks and voids in case of overmolding etc.

The glass sealing part 6 of this embodiment may deteriorate when dew condensation generates depending on the use conditions of the device although it is excellent in weather resistance as described earlier. Even in this case, although the device is desirably composed so as not to have the dew condensation, the glass sealing portion 6 can be prevented from deteriorating due to the dew condensation at high temperature by coating a silicone resin etc. on the surface of the glass sealing portion 6. The coating material coated on the surface of the glass sealing portion 6 preferably includes an inorganic material such as a SiO₂ based material and Al₂O₃ based material which has not only humidity resistance but also acid resistance and alkali resistance.

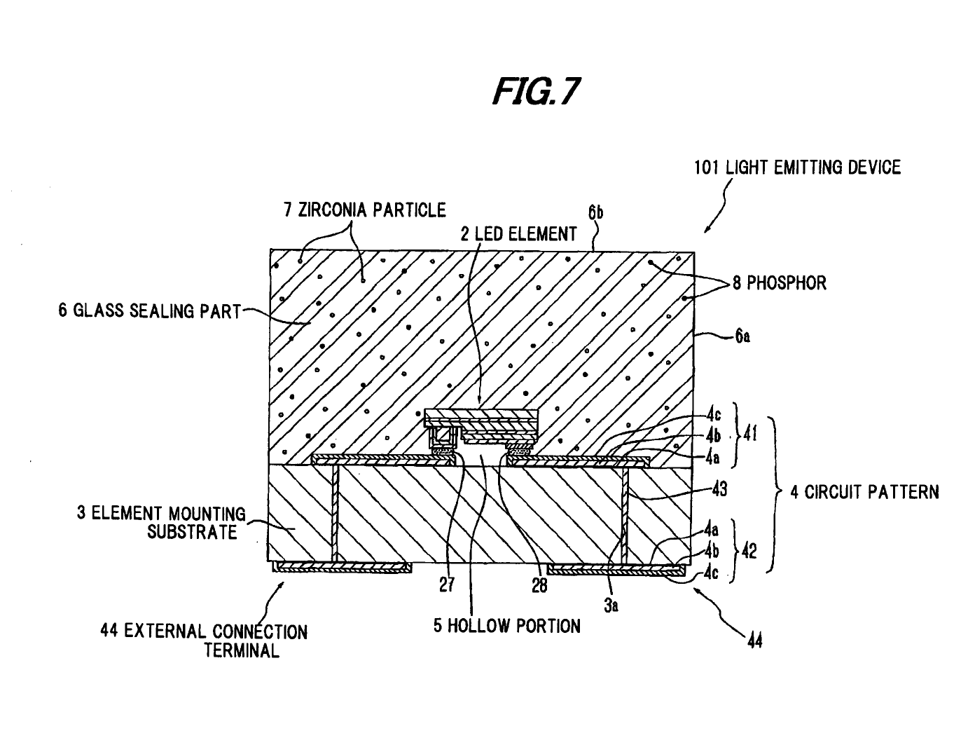

The glass sealing part 6 may include phosphor 8. FIG. 7 is a cross sectional view showing a light emitting device 101 in a modification of the first embodiment. As shown in FIG. 7, the light emitting device 101 has the same composition as the first embodiment except that it includes the phosphor 8. The phosphor 8 is a yellow phosphor to emit a yellow light with a peak wavelength in yellow wavelength region by being excited blue light emitted from the MQW layer 23. In this embodiment, the phosphor 8 is made of a YAG (yttrium aluminum garnet) phosphor, and it has an average particle diameter of 10 μm and included 2.2% by weight in the glass sealing part 6. Alternatively, the phosphor 8 may be a silicate phosphor or a mixture of YAG and silicate phosphors at a given ratio.

In the light emitting device 101, a part of blue light emitted from the LED element 2 is converted into yellow light by the phosphor 8 in the glass sealing part 6, and the remainder is discharged out of the glass sealing part 6 without being wavelength-converted.

If the diameter of the phosphor 8 is too small, light absorption efficiency thereof deteriorates. Therefore, the diameter of the phosphor 8 needs to be ten times or more the wavelength of light emitted from the LED element 2. The phosphor 8 has preferably an average particle diameter of about 10 μm which is needed to be greater than the zirconia particles 7.

Thus, light discharged from the glass sealing part 6 has peak wavelengths in yellow and blue regions, so that white light is radiated out of the device.

Here, since light is diffused by the zirconia particles 7 in the glass sealing part 6, the wavelength conversion efficiency of the phosphor 8 can be enhanced.

Since the phosphor 8 is dispersed uniformly in the glass sealing part 6, light emitted from the LED element 2 can be uniformly wavelength-converted regardless of the radiation angle, so that there occurs no unevenness in emission color among lights discharged outside.

As compared to the case that the zirconia particles 7 are not dispersed in the glass, the same chromaticity can be obtained by the light diffusion effect of the zirconia particles 7 even when the contents of the phosphor 8 in the glass sealing part 6 is reduced. Therefore, by reducing the contents of the phosphor 8, the manufacturing cost can be lowered, fragility in glass strength caused by the phosphor 8 can be prevented, and the light emitting device 101 can be provided with a blue and yellow light distribution.

Also in the light emitting device 101, light to be confined within the glass sealing part 6 in case of having no zirconia particles 7 can be extracted from the glass sealing part 6. Thus, by using the glass material, deterioration of the sealing part for the LED element 2 can be prevented, and reduction in light extraction efficiency can be prevented even when the glass sealing part 6 is formed into rectangular solid.

### Second Embodiment

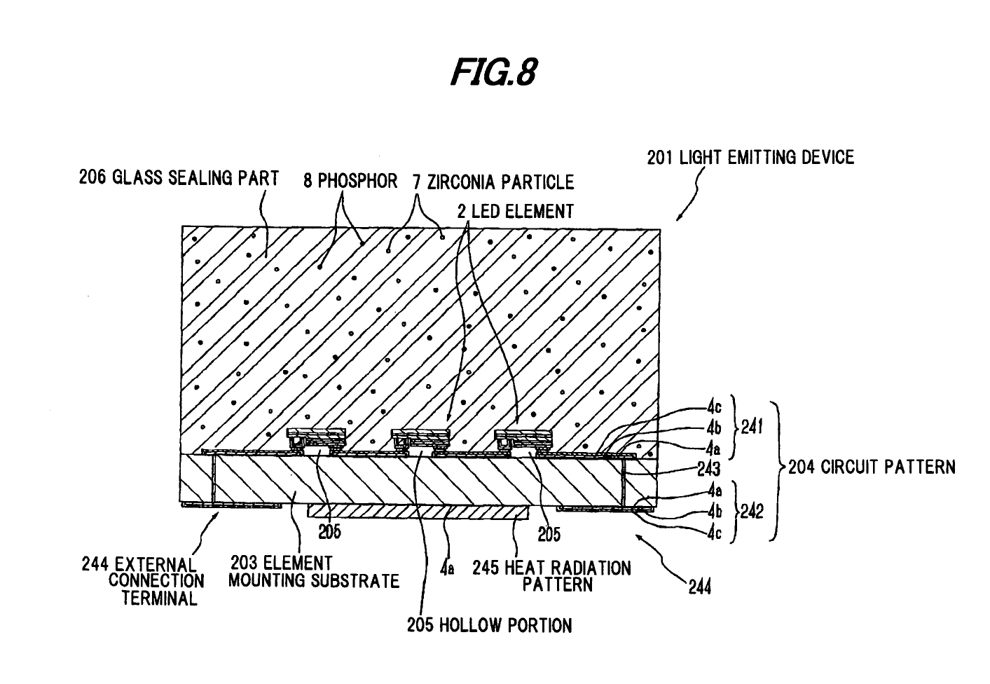

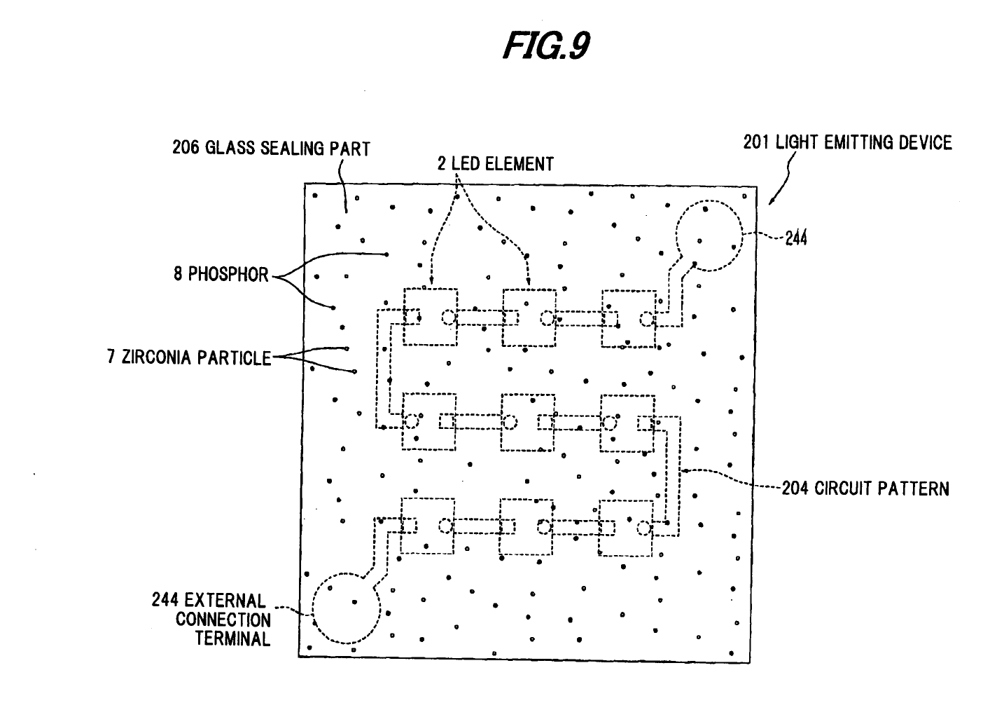

FIGS. 8 and 9 show the second embodiment of the invention. FIG. 8 is a cross sectional view showing a light emitting device in the second preferred embodiment according to the invention, and FIG. 9 is a top view showing a circuit pattern formed on an element mounting substrate. Hereinafter, like components will be indicated by the same numerals as used above and explanations thereof will be omitted.

As shown in FIG. 8, the light emitting device 201 is composed of plural flip-chip type GaN based LED elements 2, and a multilayer element mounting substrate 203 to mount the plural LED elements 2 thereon. The light emitting device 201 is further composed of a circuit pattern 204, where a surface pattern 241, a back surface pattern 242 and a via pattern 243 are formed on the top surface, back surface and inside, respectively, of the element mounting substrate 203. A hollow portion 205 into which the sealing glass is not penetrated is formed between the LED element 2 and the element mounting substrate 203.

The surface pattern 241 and the back surface pattern 242 are each composed of a W layer 4a formed on the element mounting substrate 203, and a Ni thin layer 4b and an Au thin layer 4c formed on the surface of the W layer 4a by plating. A heat radiation pattern 245 is formed on the opposite side of the mounting surface of the element mounting substrate 203 so as to externally radiate heat generated from the LED elements 2. The heat radiation pattern 245 is produced by the same process as the back surface pattern 242 and includes the W layer 4a.

The light emitting device 201 is further composed of a glass sealing part 206 to seal the LED elements 2, being bonded to the element mounting substrate 203 and containing the phosphor 8 therein.

As shown in FIG. 9, the nine LED elements 2 to emit blue light are mounted 3×3 in the length and width directions on the one element mounting substrate 203. In this embodiment, the LED elements 2 are arranged at intervals of 600 μm in the length and width directions. The p-side electrode 25 is formed of ITO (indium tin oxide). The LED element 2 is formed 100 μm thick and 340 μm square, and has a thermal expansion coefficient (α) of 7×10⁻⁶/° C.

The element mounting substrate 203 is formed of polycrystalline alumina (Al₂O₃) sintered material, formed 0.25 mm thick and has a thermal expansion coefficient of 7×10⁻⁶/° C. The element mounting substrate 203 is formed 2.5 mm square in top view. The LED elements 2 are electrically series connected each other by the circuit pattern 204. The back surface pattern 242 of the circuit pattern 204 has two external connection terminals 244 disposed diagonally near the corner (i.e., upper right and lower left in FIG. 9) of the light emitting device 201. By applying a voltage between the external connection terminals 244, the nine LED elements 2 can emit light. The surface pattern 241 of the circuit pattern 204 is formed with a 0.1 mm wide fine wire pattern.

The glass sealing part 206 is formed of a ZnO—B₂O₃—SiO₂—Nb₂O₅—Na₂O—Li₂O based heat melting glass in which the zirconia particles 7 and the phosphors 8 are dispersed uniformly. The glass sealing part 206 is also formed by bonding the plate diffusing particle-dispersed glass produced from the mixed powder of the zirconia particles, the phosphor and the glass onto the element mounting substrate 203 by the hot pressing as conducted in the first embodiment.

As shown in FIG. 8, the glass sealing part 206 is formed rectangular solid on the element mounting substrate 203 and has a thickness of 1.2 mm. A side 206a of the glass sealing part 206 is formed by cutting by a dicer the element mounting substrate 203 with the plate glass bonded to the element mounting substrate 203 by the hot pressing. A top surface 206b of the glass sealing part 206 composes a surface of the plate glass bonded to the element mounting substrate 203 by the hot pressing.

The heat melting glass has a glass transition temperature (Tg) of 490° C. and a yielding point (At) of 520° C., where the glass transition temperature (Tg) is sufficiently low as compared to the formation temperature of the epitaxial growth layer of the LED element 2. In this embodiment, the glass transition temperature (Tg) is 200° C. or more lower than the formation temperature of the epitaxial growth layer. The heat melting glass has a thermal expansion coefficient (α) of 6×10⁻⁶/° C. in the range of 100 to 300° C. The thermal expansion coefficient (α) becomes larger than this as the processing temperature is beyond the glass transition temperature (Tg). Thus, the heat melting glass is bonded to the element mounting substrate 203 at about 600° C. so as to allow the hot pressing. The heat melting glass of the glass sealing part 206 has a refractive index of 1.7.

The light emitting device 201 thus composed is increased in width of the glass sealing part 206 as compared to the case of using one LED element 2 since it uses the plural LED elements 2. Therefore, where the plural LED elements 2 are mounted and the zirconia particles 7 are not included in the glass sealing part 206, the amount of light confined in the glass sealing part 206 increases. However, the light emitting device 201 is composed such that the zirconia particles 7 are dispersed in the glass sealing part 206, so that, of lights emitted from the LED elements 2, light being irradiated to the zirconia particles 7 is diffused thereby in the glass sealing part 206 and then reaches the light extraction surface of the glass sealing part 206.

Thus, by the light emitting device 201, light to be confined within the glass sealing part 206 in case of having no zirconia particles 7 can be extracted from the glass sealing part 206. Therefore, by using the glass material, deterioration of the sealing part for the LED element 2 can be prevented, and reduction in light extraction efficiency can be prevented even when the glass sealing part 206 is formed into rectangular solid as well as having the increased width.

Further, according as the width of the glass sealing part 206 increases, the difference in optical path length in the glass sealing part 206 increases. Thereby, the difference in wavelength conversion efficiency by the phosphor 8 increases among the optical paths so as to cause unevenness in emission color of light extracted from the glass sealing part 206.

However, in the light emitting device 201 of this embodiment, light can be diffused by the zirconia particles 7 in the glass sealing part 206 so that the difference in optical path length can be reduced to lower unevenness in emission color of light extracted from the glass sealing part 206. Further, since the phosphors 8 are uniformly dispersed in the glass sealing part 206, light emitted from the LED element 2 can be uniformly wavelength-converted regardless of the radiation angle, so that there occurs no unevenness in emission color among lights discharged outside. Also, since light is diffused by the zirconia particles 7 in the glass sealing part 206, the wavelength conversion efficiency of the phosphor 8 can be enhanced. Although the plural LED elements 2 may cause unevenness in brightness among lights discharged outside from the respective LED elements 2, the unevenness in brightness among the LED elements 2 can be reduced by the diffusion effect of the zirconia particles 7.

Although the plural LED elements 2 are compactly mounted on the one element mounting substrate 203, the light emitting device 201 can have good reliability without generating cracks since the LED element 2 and the glass sealing portion 206 has substantially the same thermal expansion coefficient. Further, good glass bonding strength can be secured between the glass sealing portion 206 and the element mounting substrate 203 since they have substantially the same thermal expansion coefficient.

By using the element mounting substrate 203 of Al₂O₃, a stable heat radiation performance can be obtained even when the GaN based LED elements 2 to cause a large heat generation are compactly mounted.

By providing the heat radiation pattern 245 on the back surface of the element mounting substrate 203, heat generated during the emission of the nine LED elements 2 mounted compactly can be rapidly conducted through the heat radiation pattern 245 to a heat sink etc.

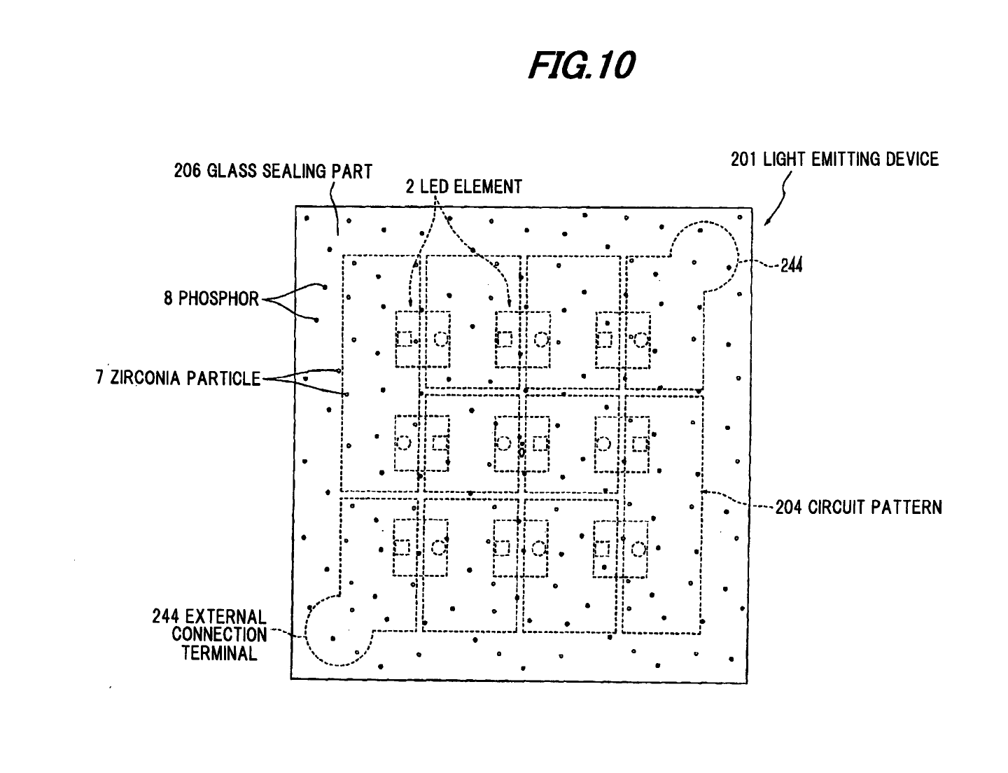

Although in the second embodiment the LED elements 2 are electrically connected through the circuit pattern 204 with the Au layer 4c as a top layer, most part of the mounting surface of the element mounting substrate 203 may be covered by, e.g., the circuit pattern 204 as shown in FIG. 10. In this case, the top layer of the circuit pattern 204 is preferably formed of Ag. As shown in FIG. 10, the mounting surface is covered by the circuit pattern 204 except edge regions of the element mounting substrate 203 and insulation regions between the circuit patterns 204. For example, in FIG. 10, the mounting surface of the element mounting substrate 203 is about 90% covered by the circuit pattern 204. Since most part of the mounting surface of the element mounting substrate 203 is thus covered by Ag, light emitted from the LED element 2 can be efficiently reflected by the circuit pattern 204. Here, the reflectivity of Ag is more than 90% to light with a wavelength more than 370 nm, so that ultraviolet light emitted from the LED element 2 can be efficiently used even when the LED element 2 emits light with a wavelength of 370 nm to 410 nm. In this case, phosphor 8 is preferably composed of blue, green and red phosphors.

A part of ZnO of the B₂O₃—SiO₂—Li₂O—Na₂O—ZnO—Nb₂O₃-based heat melting glass may be replaced by Bi₂O₃ so as to further increase the refractive index of the heat melting glass. The refractive index of the heat melting glass is preferably 1.8. In case of using the heat melting glass with a refractive index of 1.8, the LED element is desirably provided with a substrate with a refractive index (nd) not less than 1.8 so that the light extraction efficiency from the LED element can be enhanced to increase the emission efficiency (or external luminous efficiency). For example, the substrate with a refractive index not less than 1.8 includes a Ga₂O₃ substrate, GaN substrate and SiC substrate.

Although in the first and second embodiments the zirconia particles 7 are used as a light diffusing particle, the diffusion effect can be also obtained by using, e.g., alumina particles or silica particles. Thus, the material of the light diffusing particle may be arbitrarily chosen. In view of light transmissivity, a white material is preferred, and in view of stability in the glass processing, the material has preferably a melting point higher than the processing temperature.

In addition to the diffusing particles, the glass sealing parts 6, 206 may have fine voids therein such that the diffusion effect can be obtained by the voids. Meanwhile, the diffusion effect can be obtained only by the voids without dispersing the diffusing particles in the glass sealing parts 6, 206. When the voids in the glass sealing parts 6, 206 have a diameter of 0.2 μm to 10 μm, the light extraction efficiency can be preferably enhanced by the diffusion thereof while preventing the physical influence such as fragility of the glass. When the diameter is 0.5 μm to 4 μm corresponds to one to several times wavelength of blue light, Mie scattering (i.e., scattering by particles with a diameter at wavelength level) can be preferably yielded.

In the first and second embodiments, the plate phosphor-dispersed glass is produced from the mixed powder of the phosphor and the glass such that the plate glass is bonded to the element mounting substrate by hot pressing. Alternatively, after the mixed power is produced in the mixing step, the mixed power may be melted on the element mounting substrate in vacuum and high temperature atmosphere and then solidified to provide for the diffusing particle-dispersed glass, where the LED elements are sealed by the diffusing particle-dispersed glass fusion-bonded to the element mounting substrate. In this case, the voids as described above are advantageously easy to form in the glass.

Although in the first and second embodiments the element mounting substrate is formed of alumina (Al₂O₃), it may be formed of ceramics other than the alumina. For example, BeO (thermal expansion coefficient (α): 7.6×10⁻⁶/° C., thermal conductivity: 250 W/(m·k)) may be used which is a ceramic substrate with thermal conductivity higher than the alumina. The BeO substrate can also yield a good sealing property with the diffusing particle-dispersed glass.

The other thermal conductivity substrates available can be a W—Cu substrate. The W—Cu substrate includes a W90-Cu10 substrate (thermal expansion coefficient (α): 6.5×10⁻⁶/° C., thermal conductivity: 180 W/(m·k)) and a W85-Cu15 substrate (thermal expansion coefficient (α): 7.2×10⁻⁶/° C., thermal conductivity: 190 W/(m·k)). The W—Cu substrate can have a high thermal conductivity as well as securing good bonding strength with the glass sealing part, and can be sufficiently adapted for high-brightness and high-output LED's.

Although in the first and second embodiments the light emitting element is exemplified by the LED element, the light emitting element of the invention is not limited to it.

### Third Embodiment

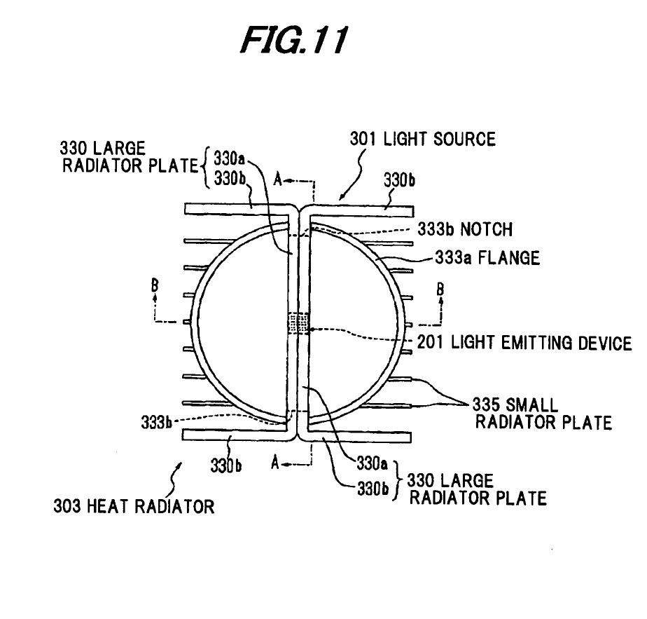

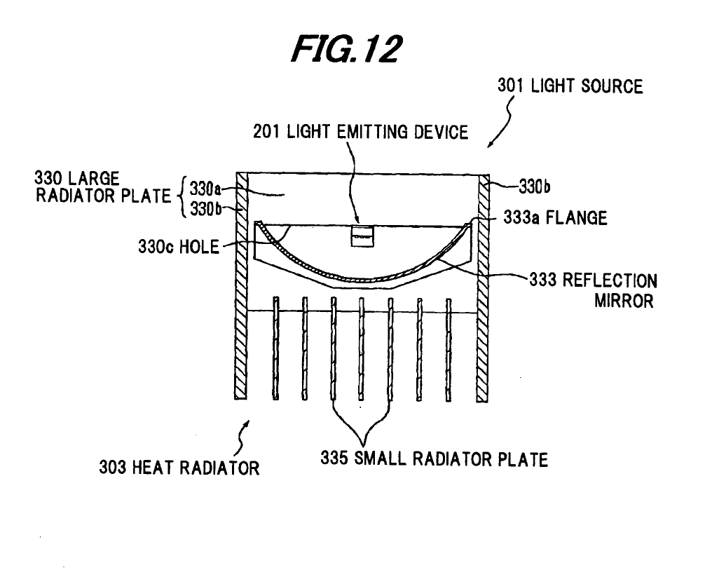

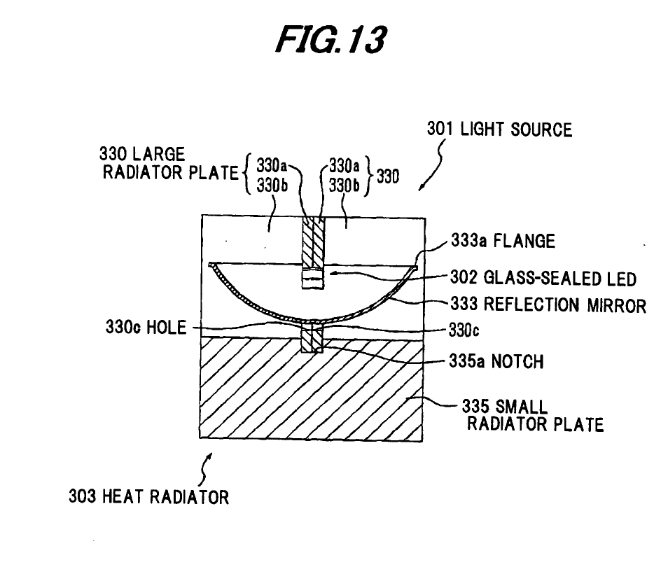

FIGS. 11 to 13 show the third preferred embodiment of the invention. FIG. 11 is a top view showing a light source in the third preferred embodiment according to the invention. FIG. 12 is a cross sectional view cut along a line A-A in FIG. 11. FIG. 13 is a cross sectional view cut along a line B-B in FIG. 11.

As shown in FIG. 11, the light source 301 is composed of the light emitting device 201 of the second embodiment, and a heat radiator 303 on which the light emitting device 201 is mounted. The heat radiation pattern 245 (See FIG. 8) of the light emitting device 201 is directly bonded to the heat radiator 303. The heat radiator 303 is composed of plural large radiator plates 330 and plural small radiator plates 335 which are formed with a high thermal conductivity and integrated through Au—Sn bonding. In other words, the heat radiator 303 has the plural thermally conductive radiator plates 330, 335 which are separate from each other at a part thereof.

The heat radiator 303 is composed of the two large radiator plates 330 of copper and 1.25 mm in thickness and the seven small radiator plates 335 of copper and 0.1 mm in thickness. The large radiator plate 330 is composed of a central portion 330a whose plate surface faces right and left and on end face of which the light emitting device 201 is mounted, and an extension portion 330b which extends right and left from the front end and back end. As shown in FIG. 12, the lower end of the central portion 330a is located above the lower end of the extension portion 330b. The two large radiator plates 330 are face-contacted each other at an inner surface of the central portion 330a and bonded through Au—Sn bonding.

The central portion 330a of the large radiator plate 330 is provided with a hole 330c in which the light emitting device 201 and a reflection mirror 333 are arranged. The light emitting device 201 is disposed at an upper edge of the hole 330c so as to emit light downwardly. The reflection mirror 333 is disposed below the light emitting device 201 so as to reflect upwardly light emitted from the light emitting device 201. The reflection mirror 333 is formed of, e.g., a resin with metal deposited on its surface or a metal plate, and shaped like a paraboloid of revolution opened upward with a focal point at the light emitting device 201. The reflection mirror 333 composes a converging optical system to collect upwardly light emitted from the light emitting device 201. The reflection mirror 333 is provided with a flange portion 333a extending outwardly at periphery thereof. As shown in FIG. 11, the flange portion 333a is provided with a notch 333b for receiving the large radiator plate 330, where the reflection mirror 333 is engaged by the large radiator plate 330.

The small radiator plates 335 are arranged with its plate surface facing forward and back, and connected to the lower end of the central portion 330a of the large radiator plate 330. As shown in FIG. 13, the small radiator plates 335 are provided with a notch 335a for receiving the large radiator plate 330 at its top center. The large radiator plate 330 and the small radiator plate 335 are bonded through Au—Sn bonding.

In the light source 301, the heat radiation pattern 245 is directly bonded to the metal so as to dissipate heat through the heat radiation pattern 245 to the heat radiator 303 to reduce temperature rise of the LED elements 2. Thus, in the light emitting device 201 with the plural LED elements 2 mounted thereon, heat conduction to the adjacent LED elements 2 can be prevented.

Further, the light emitting device 201 can be downsized which needs no outer frame required for a silicone resin sealed device etc. Even when downsized, since the difference in thermal expansion coefficient among components is small and all components are at low level of 10⁻⁶/° C. in thermal expansion coefficient, peeling between the components can be prevented which may be caused by heat during the mounting process or spontaneous heat during the device operation. Such a small and high brightness light source can offer higher precision in optical control.

Further, when the light emitting device 201 with the LED elements 2 mounted thereon is applied to the focusing optical system, at infinity where the image of the light emitting device 201 is formed, light radiated from the light emitting device 201 has no unevenness in emission color so that emission color can be uniformed in the lighting range.

The light emitting device 201 is not exposed so as to simplify the appearance and to protect the light emitting device 201 from outside. By using the reflection mirror 333, light emitted from the light emitting device 201 can be externally discharged to have a given light distribution. The large radiator plate 330 defining the outer circumference of the light source 301 may be formed relatively thick so as to secure the strength and durability thereof. The small radiator plate 335 disposed inside the light source 301 may be formed relatively thin so as to make the entire light source 301 lightweight.

Although in the third embodiment the light emitting device 201 is provided with the plural LED elements, it may be provided with one LED element as well as a focusing optical system.

The heat radiator 303 may be composed arbitrarily, where the heat radiation pattern can be directly bonded or contacted with the metal so as to reduce the temperature rise of LED element.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting device, comprising:
a light emitting element;
a mounting portion on which the light emitting element is mounted; and
a sealing portion formed on the mounting portion for sealing the light emitting element,
wherein the sealing portion comprises a glass material and a light diffusing particle for diffusing light emitted from the light emitting element, and
the sealing portion is shaped like a rectangular solid.

2. The light emitting device according to claim 1, wherein:
the sealing portion is bonded to the mounting portion by hot pressing, and
the light diffusing particle comprises a melting point higher than temperature during the hot pressing.

3. The light emitting device according to claim 1, wherein:
the light diffusing particle comprises a particle diameter corresponding to one to nine times a wavelength of light emitted from the light emitting element.

4. The light emitting device according to claim 1, wherein:
the light diffusing particle comprises a white particle.

5. The light emitting device according to claim 4, wherein:
the light diffusing particle comprises a zirconia particle.

6. The light emitting device according to claim 4, wherein:
the light diffusing particle comprises an alumina particle.

7. The light emitting device according to claim 1, wherein:
the light emitting element comprises a plurality of light emitting element on the one mounting portion.

8. The light emitting device according to claim 1, wherein:
the glass material comprises a void formed therein.

9. The light emitting device according to claim 1, wherein:
the sealing portion further comprises a phosphor for radiating a wavelength-converted light when being excited by light emitted from the light emitting element.

10. The light emitting device according to claim 1, wherein:
the glass material comprises a ZnO—SiO₂—R₂O-based glass material, where R is an element selected from group I elements.

11. A light source, comprising:
the light emitting device according to claim 1; and
a focusing optical system for collecting light emitted from the light emitting device in a predetermined direction.

12. The light source according to claim 11, wherein:
the light emitting device further comprises a heat radiation pattern formed on the mounting portion, and
the light source further comprises a heat radiator connected to the heat radiation pattern.

13. A method for making the light emitting device according to claim 1, comprising:
mixing a powder glass with a powder light diffusing particle to form a mixed powder with the light diffusing particle dispersed in the glass;
melting the mixed powder and then solidifying the melted to have a plate diffusing particle-dispersed glass;
fusion-bonding the diffusing particle-dispersed glass to the mounting portion with the plural light emitting elements mounted thereon by hot pressing to have an intermediate product comprising the plural light emitting elements sealed by the diffusing particle-dispersed glass formed on the mounting portion; and
dividing the intermediate product by a dividing means to have the light emitting device.
